(19) United States
(12) Patent Application Publication
(10) Pub. No.: US 2022/0115717 A1
(43) Pub. Date: Apr. 14, 2022

(54) APPARATUS FOR DETECTING THERMAL RUNAWAY OF BATTERY FOR ELECTRIC VEHICLE

(71) Applicants: HYUNDAI MOTOR COMPANY, Seoul (KR); KIA CORPORATION, Seoul (KR)

(72) Inventor: Hyunchang KANG, Seoul (KR)

(73) Assignees: HYUNDAI MOTOR COMPANY, Seoul (KR); KIA CORPORATION, Seoul (KR)

(21) Appl. No.: 17/365,401

(22) Filed: Jul. 1, 2021

(30) Foreign Application Priority Data
Oct. 14, 2020 (KR) 10-2020-0132379

(51) Int. Cl. H01M 10/48; H01M 10/42

(52) U.S. Cl. CPC H01M 10/48; H01M 2220/20; H01M 10/4257

(57) ABSTRACT

An apparatus for detecting a thermal runaway of a battery for an electric vehicle may include: a battery module including a plurality of battery cells each having a pouch main body and a pair of electrode leads provided at ends of the pouch main body; and a printed circuit board mounted with a gas sensor for sensing a gas amount exhausted from the plurality of battery cells.

### CROSS-REFERENCE TO RELATED APPLICATION

This application claims priority to and the benefit of Korean Patent Application No. 10-2020-0132379, filed on Oct. 14, 2020, the entire contents of which are incorporated herein by reference.

### FIELD

The present disclosure relates to an apparatus for detecting a thermal runaway of a battery for an electric vehicle.

### BACKGROUND

The statements in this section merely provide background information related to the present disclosure and may not constitute prior art.

An electric vehicle is a vehicle that uses an electric motor operated with electrical energy supplied from a battery.

Since such an electric vehicle uses a battery in which a plurality of secondary cells capable of being charged and discharged are formed as a single pack as a main power source, it has the advantage of no emissions and very little noise.

In addition, a hybrid vehicle is a vehicle that uses two or more power sources to propel the vehicle, for example, an internal combustion engine powered by fuel and an electric motor powered by a battery.

In the vehicle using electrical energy as described above, since performance of the battery directly affects performance of the vehicle, a battery management system is required to efficiently manage charging and discharging of each battery cell by measuring a voltage of each battery cell, and a voltage and current of an entire battery, and to ensure maximum performance of the battery cell by determining whether each battery cell is degraded.

Recently, the use of lithium-ion batteries in such electric vehicles is increasing. The lithium-ion battery is a type of rechargeable battery, and has a multilayer structure including a positive electrode activated by various mixed oxides or olivine, a negative electrode activated by a specific carbon, and a separator immersed in an organic electrolyte.

In a normal operation state thereof, electrical energy is converted and stored as chemical energy during charging, and the stored chemical energy is converted into electrical energy during discharging. In more detail, during charging, lithium in the positive electrode is ionized to move layer by layer toward the negative electrode. During discharging, ions move to the positive electrode to return to their original compound.

In such a lithium-ion battery, a state known as self-heating may occur in extreme situations of overvoltage, overcurrent, or overtemperature. Due to the self-heating, the lithium-ion battery may enter a thermal runaway state. The self-heating means a state in which a temperature inside a battery cell rises due to an electrical-chemical structure inside the battery cell.

When the thermal runaway occurs inside a battery module, it may cause very extreme and severe damage. When the thermal runaway occurs, a very little amount of oxygen may be generated and an internal temperature may rise to 800 degrees Celsius or more.

When such a situation occurs, a fire may occur inside the vehicle, excessive gas may be generated, or a case in which a lithium-ion battery cell is accommodated may be destroyed. Particularly, when a fire occurs, it may cause very serious damage to a driver in the vehicle.

The above information disclosed in this Background section is only for enhancement of understanding of the background of the present disclosure, and therefore it may contain information that does not form the prior art that is already known in this country to a person of ordinary skill in the art.

### SUMMARY

The present disclosure provides an apparatus for detecting a thermal runaway of a battery for an electric vehicle that may detect a thermal runaway of a battery for an electric vehicle and warn an occupant of the vehicle of a danger thereof.

An apparatus for detecting a thermal runaway of a battery for an electric vehicle according to an exemplary form of the present disclosure may include: a battery module including a plurality of battery cells, where each battery cell of the plurality of battery cells is a pouch type and includes a pouch main body and a pair of electrode leads respectively provided at first and second ends of the pouch main body; and a printed circuit board mounted with at least one gas sensor for sensing a gas amount exhausted from each battery cell of the plurality of battery cells.

The printed circuit board mounted with the gas sensor may be installed at an end of a battery cell assembly including the plurality of battery cells.

The gas sensor mounted on the printed circuit board may be installed adjacent between the pouch main body and the electrode lead.

The apparatus according to an exemplary form of the present disclosure may further include a controller that determines a thermal runaway of each battery cell of the plurality of battery cells based on the sensed gas amount of the battery cell(s) transmitted through the printed circuit board; and a warning part that notifies an occupant through an alarm when a thermal runaway occurs in the battery cell(s).

An apparatus for detecting a thermal runaway of a battery for an electric vehicle according to another exemplary form of the present disclosure may include a battery module including a plurality of battery cell of a prismatic type having a prismatic main body and a venting portion provided on upper portion of the prismatic main body; and a printed circuit board mounted with a gas sensor for sensing gas amount exhausted from the battery cell.

The printed circuit board mounted with the gas sensor may be installed at an end of the battery cell assembly including the plurality of battery cell.

The gas sensor mounted on the printed circuit board may be arranged adjacent to the venting portion provided on the prismatic main body.

The apparatus according to another exemplary form of the present disclosure may further include a controller that determines whether the battery cell is in a thermal runaway condition based on the gas amount of the battery cell transmitted through the printed circuit board; and a warning part that notifies an occupant through an alarm when a thermal runaway occurs in the battery cell.

According to the apparatus for detecting the thermal runaway of the battery for the electric vehicle according to the forms of the present disclosure as described above, by detecting a gas amount discharged from a battery cell through a gas sensor of a sensor board, and predicting a thermal runaway of the battery cell, it is possible to provide information on whether or not a danger occurs to occupants of a vehicle.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 illustrates a block diagram of an apparatus for detecting a thermal runaway according to an exemplary form of the present disclosure;

FIG. 2 illustrates an exploded perspective view of a battery module according to an exemplary form of the present disclosure;

FIG. 3 illustrates a relationship between a battery cell and a printed circuit board according to an exemplary form of the present disclosure;

FIG. 4 illustrates an exploded perspective view of a battery module according another exemplary form of the present disclosure;

FIG. 5 illustrates a perspective view of a battery cell according to another exemplary form of the present disclosure; and

FIG. 6 and FIG. 7 illustrate graphs of a sensing signal according to some forms of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

The present disclosure will be described more fully hereinafter with reference to the accompanying drawings, in which exemplary forms of the present disclosure are shown. As those skilled in the art would realize, the described forms may be modified in various different ways, all without departing from the spirit or scope of the present disclosure.

In order to clearly describe the present disclosure, parts that are irrelevant to the description are omitted, and identical or similar constituent elements throughout the specification are denoted by the same reference numerals.

In addition, since the size and thickness of each configuration shown in the drawings are arbitrarily shown for convenience of description, the present disclosure is not necessarily limited to configurations illustrated in the drawings, and in order to clearly illustrate several parts and areas, enlarged thicknesses are shown.

Hereinafter, an apparatus for detecting a thermal runaway of a battery for an electric vehicle according to some exemplary forms of the present disclosure will be described in detail with reference to the accompanying drawings.

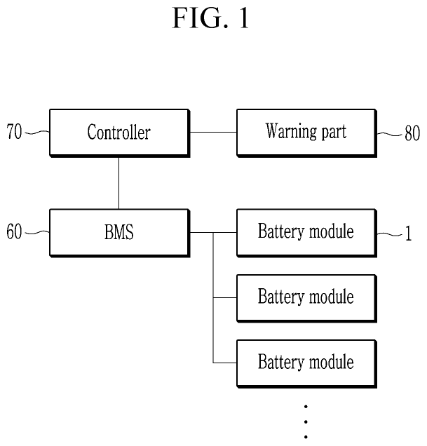

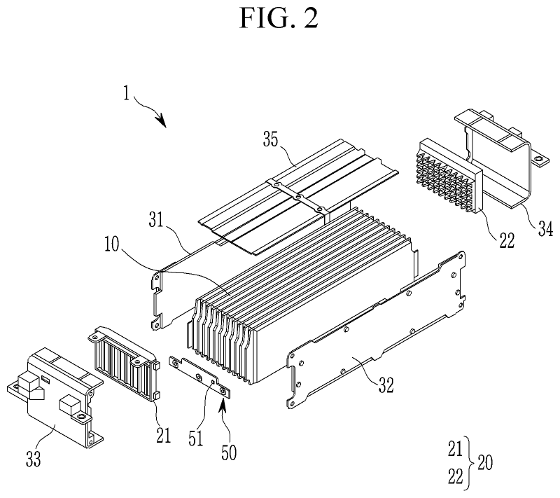

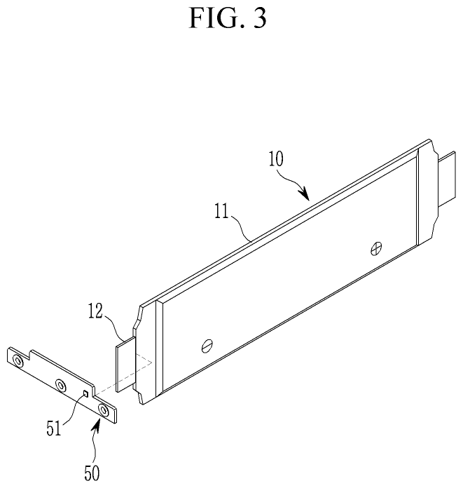

FIG. 1 illustrates a block diagram of an apparatus for detecting a thermal runaway according to an exemplary form of the present disclosure. FIG. 2 illustrates an exploded perspective view of a battery module according to another form of the present disclosure. And FIG. 3 illustrates a relationship between a battery cell and a printed circuit board according to an exemplary form of the present disclosure.

As shown in FIG. 1, an apparatus for detecting a thermal runaway of a battery for an electric vehicle may include a battery module 1, a controller 70, and a warning part 80.

Referring to FIG. 2, the battery module 1 may include a plurality of battery cells 10 and a printed circuit board (PCB) 20 that are provided in an exterior case 30.

The exterior case 30 may include a left cover 31, a right cover 32, an upper cover 35, a lower cover, a front cover 33, and a rear cover 34. The left cover 31, the right cover 32, the upper cover 35, the lower cover, the front cover 33, and the rear cover 34 are combined to form the exterior case 30, and the exterior case 30 is provided to surround an outer periphery of the plurality of battery cells 10, and the printed circuit board 20 is provided between the exterior case 30 and the plurality of battery cells 10.

In an exemplary form of the present disclosure, the battery cell 10 is a type of a pouch cell type, and includes a pouch main body 11 and electrode leads provided an both ends of the pouch main body 11.

The pouch main body 11 accommodates an electrode assembly (not shown), and includes a multi-layered pouch film including a first resin layer, a metal layer, and a second resin layer. The electrode leads 12 is electrically connected to the electrode assembly and the printed circuit board 20.

Since the pouch main body 11 is heat-sealed with the electrode leads 12 in a state where the electrode leads 12 are drawn out to the outside, the sealing property is deteriorated in an area through which the electrode leads 12 pass. Accordingly, a sealant may be applied between the pouch main body 11 and the electrode leads 12.

The plurality of battery cells 10 are stacked in left and right directions, and the plurality of battery cells 10 are connected to in parallel and/or in series. The printed circuit boards 20 are provided at both ends of the plurality of battery cells 10 stacked in the left and right directions

In an exemplary form of the present disclosure, the plurality of battery cell 10 stacked in the left and right directions will be referred to as a battery cell assembly.

A gas sensor 51 for sensing gas amount exhausted from the battery cell 10 of a pouch type is mounted in the printed circuit board 20. In an exemplary form of the present disclosure, the gas sensor 51 may be mounted on the printed circuit board 20 provided at both ends of the battery cell assembly, and may be mounted on a separate sensor board 50, if desired. The sensor board 50 is provided at both ends of the battery cell assembly together with the printed circuit board 20, and the sensor board 50 and the printed circuit board 20 are electrically connected with each other.

The gas sensor 51 senses the gas amount exhausted from the battery cell 10, and the gas amount sensed by the gas sensor 51 is transmitted to a battery management system 60 electrically connected to the printed circuit board 20.

As described above, in the case of pouch type of the battery cell 10, since the bonding force between the pouch main body 11 and the electrode leads 12 is relatively small, the gas generated inside the pouch main body 11 is exhausted through between the pouch main body 11 and the electrode leads 12. In one form, the gas sensor 51 mounted on the printed circuit board 20 is installed adjacent between the pouch main body 11 and the electrode lead 12.

The printed circuit boards 20 provided at both ends of the battery cell assembly detect a voltage and temperature of each battery cell 10 to transmit them to a battery management system (BMS) 60.

The battery management system 60 receives battery information detected by various types of sensors (for example, a temperature sensor, a voltage sensor, etc.) through the printed circuit board 20 to determine a situation of a plurality of battery modules 1, and it manages each battery module 1 to be maintained in an optimal state.

Particularly, the battery management system 60 measures the remaining capacity of the battery, maintains a state of charge (SOC) of the battery at an appropriate level, and measures and manages a temperature of the battery.

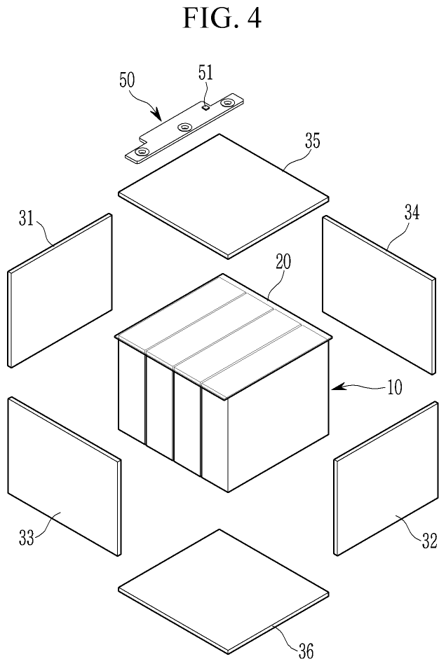

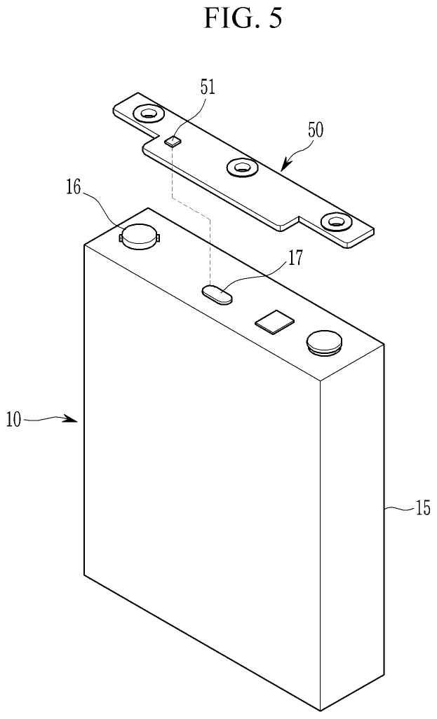

FIG. 4 illustrates an exploded perspective view of a battery module according another exemplary form of the present disclosure. FIG. 5 illustrates a perspective view of a battery cell according to another exemplary form of the present disclosure.

Referring to FIG. 4, the battery module 1 may include a plurality of battery cell 10 accommodated in an exterior case 30 and a printed circuit board 20.

Similar to the form described with reference to FIG. 2, the exterior case 30 may include a left cover 31, a right cover 32, an upper cover 35, a lower cover, a front cover 33, and a rear cover 34. The left cover 31, the right cover 32, the upper cover 35, the lower cover, the front cover 33, and the rear cover 34 are combined to form the exterior case 30, and the exterior case 30 is provided to surround an outer periphery of the plurality of battery cells 10, and the printed circuit board 20 is provided between the exterior case 30 and the plurality of battery cells 10.

In another exemplary form of the present disclosure, the battery cell 10 is a prismatic type of battery cell, and a venting portion 17 and a pair of electrodes 16 are formed on upper portion of a prismatic main body 15.

When the battery cell 10 repeats charging and discharging, a venting gas is generated in the battery cell. When an amount of the venting gas exceeds a predetermined amount, the venting gas in the battery cell 10 is exhausted outside through the venting portion 17.

The plurality of battery cells 10 are stacked in left and right directions, and the plurality of battery cells 10 are connected to in parallel and/or in series. The printed circuit boards 20 are provided at both ends of the plurality of battery cells 10 stacked in the left and right directions.

A gas sensor 51 for sensing gas amount exhausted from the battery cell 10 of a prismatic type is mounted in the printed circuit board 20. In another exemplary form of the present disclosure, the gas sensor 51 may be mounted on the printed circuit board 20 provided at both ends of the battery cell assembly, and may be mounted on a separate sensor board 50, if desired. The sensor board 50 is provided on upper end of the battery cell assembly together with the printed circuit board 20, and the sensor board 50 and the printed circuit board 20 are electrically connected with each other.

The gas sensor 51 senses the gas amount exhausted from the battery cell 10, and the gas amount sensed by the gas sensor 51 is transmitted to a battery management system 60 electrically connected to the printed circuit board 20.

As described above, in the case of the prismatic type of the battery cell 10, the venting gas generated in the battery cell 10 is exhausted outside through the venting portion 17. Accordingly, the gas sensor 51 mounted on the printed circuit board 20 is installed adjacent to the venting portion 17.

The printed circuit boards 20 provided on upper portion of the battery cell assembly detects a voltage and temperature of each battery cell 10 to transmit them to a battery management system (BMS) 60.

The battery management system 60 receives battery information detected by various types of sensors (for example, a temperature sensor, a voltage sensor, etc.) through the printed circuit board 20 to determine a situation of a plurality of battery modules 1, and it manages each battery module 1 to be maintained in an optimal state.

Particularly, the battery management system 60 measures the remaining capacity of the battery, maintains a state of charge (SOC) of the battery at an appropriate level, and measures and manages a temperature of the battery.

Meanwhile, the controller 70 may determine whether the battery cell 10 is thermally runaway from the gas amount of the battery cell 10 transmitted from the printed circuit board 20 through the battery management system 60

To this end, the controller 70 may be provided as at least one processor executed by a predetermined program, and the predetermined program is configured to perform respective steps of a method of detecting a thermal runaway of the battery cell 10 according to the form of the present disclosure.

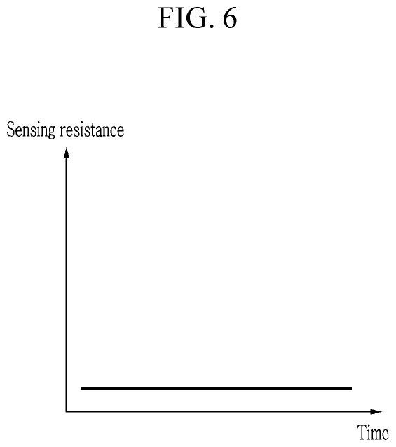

When the battery cell 10 normally operates, the sensing signal (for example, resistance value) sensed by the gas sensor 51 of the sensor board 50 is varied within a certain range (see FIG. 6).

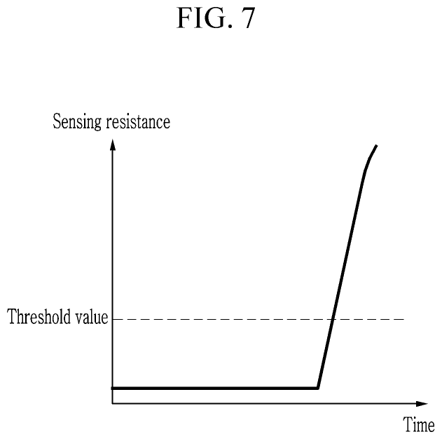

However, when the thermal runaway occurs in the battery cell 10, the sensing signal (e.g., resistance) sensed by the gas sensor 51 is rapidly increased as the venting gas amount exhausted from inside of the battery cell 10 is increased (see FIG. 7). Through this, the controller 70 may determine that the thermal runaway occurs in the battery cell 10.

When the thermal runaway occurs in the battery cell 10, the controller 70 may generate an alarm to an occupant of the vehicle through the warning part 80. The warning part 80 may be implemented through a center fascia or speaker provided in the vehicle.

The thermal runaway occurs in the battery cell 10, resulting in excessive venting gas in the battery cell 100, and a fire may occur. A very dangerous situation may occur for the occupants in the vehicle due to a cascade of fires in the vehicle due to the battery fire.

Accordingly, when the venting gas exhausted from the battery cell 10 is detected through the gas sensor 51 and the thermal runaway is predicted to occur in the battery cell 10, the controller 70 notifies the occupants of the vehicle of the situation through the warning part 80, so that it is possible to protect the occupants from the thermal runaway of the battery cell 10 and the resulting vehicle fire.

While the present disclosure has been described in connection with what is presently considered to be practical exemplary forms, it is to be understood that the present disclosure is not limited to the disclosed forms, but, on the contrary, is intended to cover various modifications and equivalent arrangements included within the spirit and scope of the present disclosure.

### DESCRIPTION OF SYMBOLS

1: battery module

10: battery cell

11: pouch main body

12: electrode lead

15: prismatic main body

16: electrode

17: venting portion

20: printed circuit board

30: exterior case

31: left cover

32: right cover

33: front cover

34: rear cover

35: upper cover

36: lower cover

50: sensor board

51: gas sensor

60: battery management system

70: controller

80: warning part

What is claimed is:

1. An apparatus for detecting a thermal runaway of a battery for an electric vehicle, the apparatus comprising:
a battery module including a plurality of battery cells, wherein each battery cell of the plurality of battery cells is a pouch type and configured to include a pouch main body and a pair of electrode leads provided at first and second ends of the pouch main body, respectively; and
a printed circuit board mounted with at least one gas sensor configured to sense a gas amount exhausted from each battery cell of the plurality of battery cells.

2. The apparatus of claim 1, wherein:
the printed circuit board is installed at an end of a battery cell assembly including the plurality of battery cells.

3. The apparatus of claim 2, wherein:
the at least one gas sensor mounted on the printed circuit board is installed adjacent between the pouch main body and an electrode lead of the pair of electrode leads.

4. The apparatus of claim 1, further comprising:
a controller configured to determine a thermal runaway of each battery cell of the plurality of battery cells based on the sensed gas amount transmitted through the printed circuit board; and
a warning part configured to notify an occupant of the electric vehicle of the thermal runaway of the plurality of battery cells.

5. An apparatus for detecting a thermal runaway of a battery for an electric vehicle, the apparatus comprising:
a battery module including a plurality of battery cells, wherein each battery cell of the plurality of battery cells is a prismatic type and configured to include a prismatic main body and a venting portion provided on an upper portion of the prismatic main body; and
a printed circuit board mounted with at least one gas sensor configured to sense a gas amount exhausted from each battery cell of the plurality of battery cells.

6. The apparatus of claim 5, wherein:
the printed circuit board is installed at an end of a battery cell assembly including the plurality of battery cells.

7. The apparatus of claim 6, wherein:
the at least one gas sensor mounted on the printed circuit board is arranged adjacent to the venting portion provided on the prismatic main body.

8. The apparatus of claim 5, wherein:
a controller configured to determine a thermal runaway of the plurality of battery cells based on the sensed gas amount of each battery cell transmitted through the printed circuit board; and
a warning part configured to notify an occupant of the electric vehicle of the thermal runaway the plurality of battery cells.
